(19) United States
(12) Patent Application Publication
(10) Pub. No.: US 2025/0074775 A1
(43) Pub. Date: Mar. 6, 2025

(54) PRODUCTION METHOD FOR DIAMOND PARTICLES

(71) Applicant: Jie TANG, Ibaraki (JP)

(72) Inventors: Jie TANG, Ibaraki (JP); Youhu CHEN, Ibaraki (JP); Luchang QIN, Ibaraki (JP)

(21) Appl. No.: 18/721,872

(22) PCT Filed: Dec. 21, 2022
(86) PCT No.: PCT/JP2022/047084

§ 371 Date: Jun. 20, 2024

(30) Foreign Application Priority Data
Dec. 21, 2021 (JP) 2021-206647

(51) Int. Cl. C01B 32/26; C30B 7/14

(52) U.S. Cl. CPC C01B 32/26; C30B 7/14; C01P 2002/90; C01P 2004/64

(57) ABSTRACT

Diamond particles are generated in a solution by carrying out a step S1 of mixing an inorganic salt such as a metal halide, a metal oxyhalide, a metal nitrate, a metal phosphate and a metal sulfate into a solvent containing 10% by volume or more of an organic solvent such as an alcohol solvent, a ketone solvent, an ester solvent, an amide solvent, a hydrocarbon solvent, an aromatic solvent, a cellosolve solvent and a halogen solvent containing carbon atoms, to prepare a mixed solution, and then carrying out an aging step S2 of holding the mixed solution under an arbitrary temperature condition for a certain period of time.

### CROSS-REFERENCE TO RELATED APPLICATIONS

The present application is a National Phase of International Application No. PCT/JP2022/047084 filed Dec. 21, 2022, which claims the benefit of priority from the prior Japanese patent application No. 2021-206647 filed on Dec. 21, 2021.

### TECHNICAL FIELD

The present invention relates to a method for producing diamond particles, and more particularly to a technique for liquid phase synthesis of diamond particles.

### BACKGROUND ART

Diamond is known to have many unique properties such as high thermal conductivity, high electrical resistivity, excellent chemical resistance, low coefficient of thermal expansion, low coefficient of friction, wide light transmission wavelength band, and biological synthesis, in addition to high hardness, and is expected to have a wide range of applications in the electronics field. Known methods for synthesizing diamond particles include high-pressure synthesis, chemical vapor deposition, and explosion methods, but all of these methods involve problems in productivity because they are performed in a closed space using large equipment.

Furthermore, as a method for synthesizing fine particles in a solution, a nanoparticle synthesis method using a solvothermal method has been conventionally proposed (see, e.g., see Patent Literature 1). The method described in Patent Literature 1 is a technique in which a liquid mixed system containing a nanoparticle precursor and a surfactant coexists with an organic solvent, and nanometer-sized particles are formed in the presence of the organic solvent, in a reaction field in a supercritical or subcritical state, and diamond is described as an example of fine particles that can be synthesized.

### CITATION LIST

### Patent Literature

Patent Literature 1: Japanese Unexamined Patent Application Publication No. 2009-233845

### SUMMARY OF INVENTION

### Technical Problem

However, the above-mentioned Patent Literature 1 does not disclose any specific method for synthesizing diamond nanoparticles. In addition, the method described in Patent Literature 1 requires reaction in a supercritical state or subcritical state in an autoclave, so there is still a problem of improving productivity. Therefore, there is a demand for the development of a liquid phase synthesis method for diamond particles that does not require special techniques or expensive equipment and has excellent productivity.

Then, an object of the present invention is to provide a method for producing diamond particles that can synthesize diamond particles in a solution by a simpler method.

### Solution to Problem

The present inventors have discovered that diamond particles can be synthesized simply by aging a mixed solution as a raw material, leading to the present invention.

That is, the method for producing diamond particles of the present invention includes a step of preparing a mixed solution by mixing an inorganic salt into a solvent containing 10% by volume or more of an organic solvent containing carbon atoms, and an aging step of holding the mixed solution under an arbitrary temperature condition for a certain period of time.

As the organic solvent, for example, at least one selected from the group consisting of alcohol solvents, ketone solvents, ester solvents, amide solvents, hydrocarbon solvents, aromatic solvents, cellosolve solvents, and halogen solvents can be used. Among these organic solvents, organic solvents containing an alkyl group having an sp3 hybrid orbital are particularly suitable.

As the inorganic salt, for example, at least one selected from the group consisting of metal halides, metal oxyhalides, metal nitrates, metal phosphates, and metal sulfates can be used. In that case, the inorganic salt may contain a metal ion of a Group 1 element, a Group 2 element, a Group 13 element, or a transition metal element.

The concentration of the inorganic salt in the mixed solution may be, for example, 0.001 to 1000 g/L.

In the aging step, the mixed solution may be held at a temperature condition of 0 to 400° C. for 0.1 to 1000 hours, and may be held under atmospheric pressure or under the saturated vapor pressure of the organic solvent.

The method for producing diamond particles of the present invention can provide diamond particles having, for example, a cubic and/or hexagonal crystal structure and having a particle size of 1 to 100 nm.

### Advantageous Effects of Invention

According to the present invention, diamond particles can be synthesized simply by mixing an organic solvent containing carbon atoms into an inorganic salt and aging the mixture, so no special techniques or expensive equipment are required and the productivity is excellent.

### BRIEF DESCRIPTION OF DRAWINGS

FIG. 1 is a flow chart showing a method for producing diamond particles according to an embodiment of the present invention.

FIG. 2 is a schematic diagram of a method for producing diamond particles according to an embodiment of the present invention.

FIG. 3 is a TEM image (photograph substituted for drawing) of diamond particles synthesized according to Example 1.

FIG. 4 is a TEM image (photograph substituted for drawing) of diamond particles synthesized according to Example 2.

FIGS. 5A to 5D are HR-TEM images (photographs substituted for drawings) of diamond particles synthesized according to Example 1 observed from various crystal orientations.

FIGS. 6A to 6D are HR-TEM images (photographs substituted for drawings) of diamond particles synthesized according to Example 2 observed from various crystal orientations.

FIGS. 7A and 7B are HR-TEM images (photographs substituted for drawings) of other diamond particles synthesized according to Example 2.

FIG. 8 is an HR-TEM image (photograph substituted for drawing) of other diamond particles synthesized according to Example 2.

### DESCRIPTION OF EMBODIMENTS

Hereinafter, embodiments for carrying out the present invention will be described in detail with reference to the accompanying drawings. Note that the present invention is not limited to the embodiments described below.

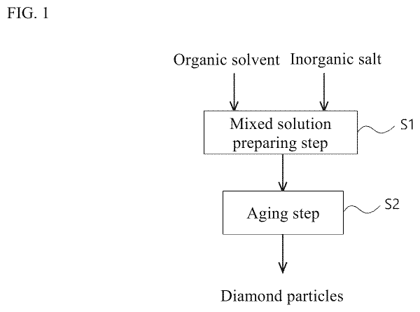

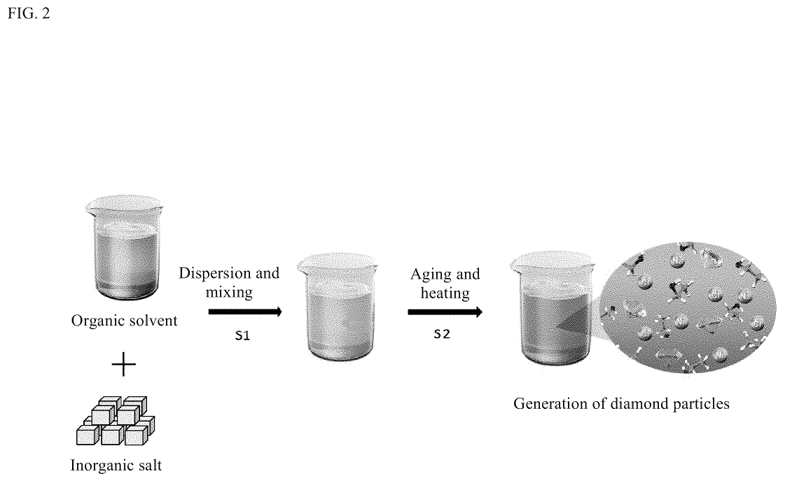

FIG. 1 is a flow chart showing the method for producing diamond particles according to the present embodiment, and FIG. 2 is a schematic diagram. As shown in FIG. 1 and FIG. 2, the method for producing diamond particles according to the embodiment of the present invention includes a step S1 of preparing a mixed solution and a step S2 of aging the mixed solution.

### [Step S1: Mixed Solution Preparation Step]

In the mixed solution preparation step S1, a solvent containing an organic solvent containing a carbon element is mixed with an inorganic salt to prepare a mixed solution.

### <Solvent>

The organic solvent contained in a solvent may be any organic solvent as long as it contains carbon atoms, and alcohol solvents, ketone solvents, ester solvents, amide solvents, hydrocarbon solvents, aromatic solvents, cellosolve solvents, and halogen solvents are preferred, and these may be used alone or in combination.

As the alcohol solvents, methanol, ethanol, 1-propanol, 2-propanol, 1-butanol, 2-butanol, isobutyl alcohol, tert-butyl alcohol, 1-pentanol, and allyl alcohol are preferred because they are easily available.

As the ketone solvents, acetone, acetylacetone, methyl ethyl ketone, isopropyl methyl ketone, isobutyl methyl ketone, 2-pentanone, 3-pentanone, cyclohexanone, and diketone are preferred because they are easily available.

As the ester solvents, ethyl acetate, propylene glycol monomethyl ether acetate, and 2-ethoxyethyl acetate are preferred because they are easily available.

As the amide solvents, N-methylpyrrolidone (NMP), N-ethyl-2-pyrrolidone, N-cyclohexyl-2-pyrrolidone, N,N-dimethylformamide (DMF) and N,N-dimethylacetamide are preferred because they are commonly used.

As the hydrocarbon solvents, those having a methyl group (—CH₃) are preferred, and specifically, n-hexane, n-heptane, n-octane, n-decane, n-dodecane, 2,3-dimethylhexane, 2-methylheptane, 2-methylhexane, 3-methylhexane and cyclohexane are preferred.

As the aromatic solvents, benzene, toluene, xylene, trimethylbenzene, ethylbenzene, methylnaphthalene, ethylnaphthalene, and dimethylnaphthalene are preferred because they are easily available.

As the cellosolve solvents, methyl cellosolve, ethyl cellosolve, butyl cellosolve, diethylene glycol monomethyl ether, diethylene glycol diethyl ether, diethylene glycol dibutyl ether, and triethylene glycol monomethyl ether are preferred because they are easily available.

As the halogen solvents, dichloromethane, trichloromethane, carbon tetrachloride, and chloroform are preferred because they are easily available.

Among the above-mentioned organic solvents, those containing an alkyl group having an sp3 hybrid orbital, typified by a methyl group (—CH₃), are particularly preferred. The organic solvent containing an alkyl group having an sp3 hybrid orbital promotes the generation of diamond particles because a hydrogen (H) atom is replaced with a carbon (C) atom and the diamond nucleus is formed, due to the inorganic salt.

The solvent to be mixed in the mixed solution may be composed of only an organic solvent containing carbon atoms, but may also contain water in addition to the organic solvent. If the solvent contains water, the inorganic salt is more likely to dissolve. When the solvent contains water, the volume of the organic solvent is preferably 10% by volume or more and less than 100% by volume, more preferably 50 to 90% by volume, based on the total volume of the solvent.

### <Inorganic Salt>

The inorganic salt functions as a catalyst in the aging step S2 described later, and generates diamond particles from a solvent. The inorganic salt to be mixed in the mixed solution is preferably at least one selected from metal halides, metal oxyhalides, metal nitrates, metal phosphates and metal sulfates. Among these inorganic salts, the halide is particularly preferred because it can easily extract other atoms bonded to carbon atoms in the organic solvent.

The inorganic salt to be mixed in the mixed solution preferably contains a metal ion of a Group 1 element, a Group 2 element, a Group 13 element, or a transition metal element. Here, examples of Group 1 elements contained in the inorganic salt include lithium (Li), sodium (Na), and potassium (K). Examples of Group 2 elements include beryllium (Be), magnesium (Mg), calcium (Ca), strontium (Sr), and barium (Ba).

Examples of Group 13 elements include aluminum (Al), gallium (Ga), and indium (In). Transition metal elements also include lanthanides, such as scandium (Sc), titanium (Ti), chromium (Cr), cobalt (Co), nickel (Ni), copper (Cu), molybdenum (Mo), niobium (Nb), lanthanum (La), cerium (Ce), and neodymium (Nd).

The concentration of the inorganic salt in the mixed solution is not particularly limited, but if it is in the range of 0.001 to 1000 g/L, diamond particles are generated. The concentration of the inorganic salt in the mixed solution is preferably 0.1 to 10 g/L, which improves the yield. From the viewpoint of improving the yield, the concentration of the inorganic salt in the mixed solution is more preferably 0.3 to 5 g/L, and even more preferably 0.5 to 1.5 g/L.

When mixing a solvent containing an organic solvent containing a carbon element with an inorganic salt, it is preferable to ultrasonically disperse the mixture using an ultrasonic homogenizer or a high-pressure homogenizer.

### [Step S2: Aging Step]

In the aging step S2, the mixed solution prepared in the mixed solution preparation step S1 is held for a certain period of time under an arbitrary temperature condition. For aging of the mixed solution, the mixed solution may be held for a certain period of time, and it is preferable to hold the mixed solution for 0.1 to 1000 hours under a temperature condition of 0 to 400° C., and more preferably for 20 to 200 hours under a temperature condition of 10 to 250° C. By carrying out aging under such conditions, diamond particles can be generated in the mixed solution.

The mixed solution may be aged under atmospheric pressure or under the saturated vapor pressure of the solvent constituting the mixed solution. When aged under the saturated vapor pressure of the solvent, the generation of diamond particles is promoted, and thus the holding time can be shortened to the range of 10 to 30 hours.

### [Other Steps]

After the aging step S2 described above, a step of removing the solvent from the mixed solution to recover the product and washing same may be performed, whereby the inorganic salt is removed to obtain diamond particles.

### [Diamond Particles]

The method for producing diamond particles according to the present embodiment described above can produce diamond particles having a cubic and/or hexagonal crystal structure and having a particle size of 0.5 nm or more and 1 mm or less. These diamond particles have a clean surface and are free of impurities, making them suitable for applications such as fluorescent semiconductor quantum dots, nanoscale magnetic sensors, in vivo tracking, and drug delivery.

Cubic diamond particles belong to the Fd3̅m space group (No. 227 in International Tables for Crystallography). Hexagonal diamond particles belong to the P63/mmc space group (No. 194 in International Tables for Crystallography). The crystal structure of diamond particles can be easily analyzed by measuring electron diffraction or fast Fourier transform (FFT) patterns.

The diamond particles produced by the method of this embodiment are each single crystal particles, and preferably have a particle size of 1 to 100 nm. This range can be used for the above-mentioned applications. The particle size of the diamond particles is more preferably 1 to 60 nm. The particle size of the diamond particles referred to here is a value obtained by measuring the particle sizes of 100 particles randomly selected from an image observed by a transmission electron microscope (TEM), and averaging them.

The diamond particles produced by the method of this embodiment may have defects within one particle. Such defects may be twin crystal and/or stacking defects. Even if the diamond particles produced by the method of this embodiment have defects, they can maintain clean surfaces and impurity-free characteristics.

The inventor has not yet elucidated the mechanism by which diamond particles are generated by liquid phase synthesis using an organic solvent containing carbon atoms and an inorganic salt, but believes as follows. It is supposed that when the carbon atom in the organic solvent has an sp3 hybrid orbital or is likely to form an sp3 hybrid orbital, the inorganic salt, which is a catalyst, pulls out atoms other than carbon bonded to the carbon atom to form a C—C bond. For example, it is supposed that, when the organic solvent has a CH₃ group and a chloride is used as the salt, the H of the CH₃⁻ in the tetrahedral bond arrangement is replaced with Cl to form CCl₄, and the Cl is replaced with C to form a diamond structure with a C—C bond.

As described in detail above, the diamond producing method of the present embodiment can synthesize diamond particles in a solution by mixing an organic solvent containing carbon atoms with an inorganic salt and by aging the mixture, so it does not require special techniques or expensive equipment, and is highly productive. The diamond particles thus obtained have clean surface and impurity-free characteristics, so they can be applied to fluorescent semiconductor quantum dots and nanoscale magnetic sensors, but if used for in vivo tracking, they can also track the implantation and regeneration ability of stem cells.

### Examples

Hereinafter, the effects of the present invention will be specifically described using Examples of the present invention. In this example, diamond particles were synthesized under the conditions shown in Table 1 below. Specifically, to a solvent (50 mL) consisting only of the organic solvents shown in Table 1 was added the inorganic salt shown in Table 1 to a predetermined concentration, and they were mixed to obtain a mixed solution which was then aged under the conditions shown in Table 1.

TABLE 1

| | Solvent | | Inorganic salt | | Aging conditions | | |
|---|---|---|---|---|---|---|---|
| | Type of organic | Organic solvent content | | Concentration | Temperature | | Time |
| Examples | solvent | (% by volume) | Type | (g/L) | (° C.) | Pressure | (H) |
| 1 | Ethanol | 100 | NaCl | 0.5 | 20 | Atmospheric pressure | 168 |
| 2 | Ethanol | 100 | NaCl | 1 | 200 | Saturated vapor | 24 |
| | | | | | | pressure | |
| 3 | Acetone | 100 | AlCl₃ | 1.5 | 200 | Saturated vapor | 24 |
| | | | | | | pressure | |
| 4 | Acetylacetone | 100 | AlCl₃ | 1.5 | 200 | Saturated vapor | 24 |
| | | | | | | pressure | |
| 5 | Ethyl acetate | 100 | AlCl₃ | 1.5 | 200 | Saturated vapor | 24 |
| | | | | | | pressure | |
| 6 | DMF | 100 | AlCl₃ | 1.5 | 200 | Saturated vapor | 24 |
| | | | | | | pressure | |
| 7 | NMP | 100 | AlCl₃ | 1.5 | 200 | Saturated vapor | 24 |
| | | | | | | pressure | |
| 8 | Ethanol | 100 | KCl | 1 | 200 | Saturated vapor | 24 |
| | | | | | | pressure | |
| 9 | Ethanol | 100 | CuCl₂ | 1 | 200 | Saturated vapor | 24 |
| | | | | | | pressure | |
| 10 | Ethanol | 100 | TiCl₄ | 1 | 200 | Saturated vapor | 24 |
| | | | | | | pressure | |

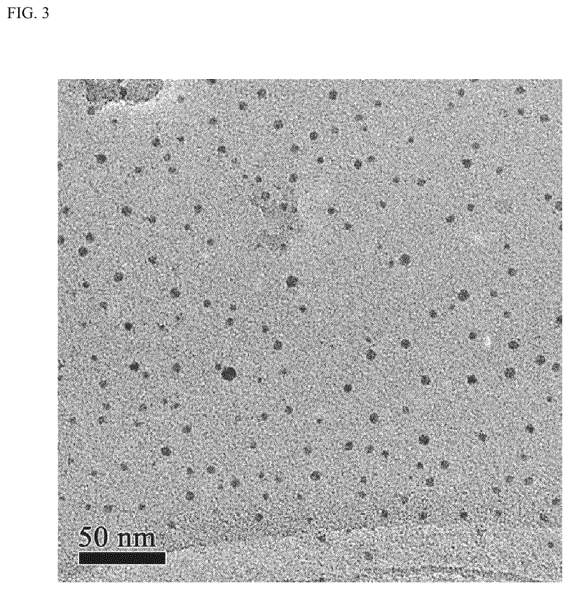

The products obtained in each example were washed multiple times with ethanol and then evaluated using a transmission electron microscope (TEM, JEM-2100F manufactured by JEOL Ltd.). The results are shown in FIGS. 3 to 8 and Table 2 below.

TABLE 2

| | Minimum | Maximum | Average | |
|---|---|---|---|---|
| | particle | particle | particle | |
| Examples | size (nm) | size (nm) | size (nm) | Crystal structure |
| 1 | 1 | 60 | 8 | Cubic and |
| | | | | hexagonal crystal |
| 2 | 1 | 30 | 12 | Cubic and |
| | | | | hexagonal crystal |
| 3 | 1 | 50 | 15 | Cubic and |
| | | | | hexagonal crystal |
| 4 | 1 | 40 | 10 | Cubic and |
| | | | | hexagonal crystal |
| 5 | 1 | 10 | 4 | Cubic and |
| | | | | hexagonal crystal |
| 6 | 1 | 10 | 5 | Cubic and |
| | | | | hexagonal crystal |
| 7 | 1 | 10 | 6 | Cubic and |
| | | | | hexagonal crystal |
| 8 | 1 | 10 | 3 | Cubic and |
| | | | | hexagonal crystal |
| 9 | 1 | 20 | 9 | Cubic and |
| | | | | hexagonal crystal |
| 10 | 1 | 30 | 8 | Cubic and |
| | | | | hexagonal crystal |

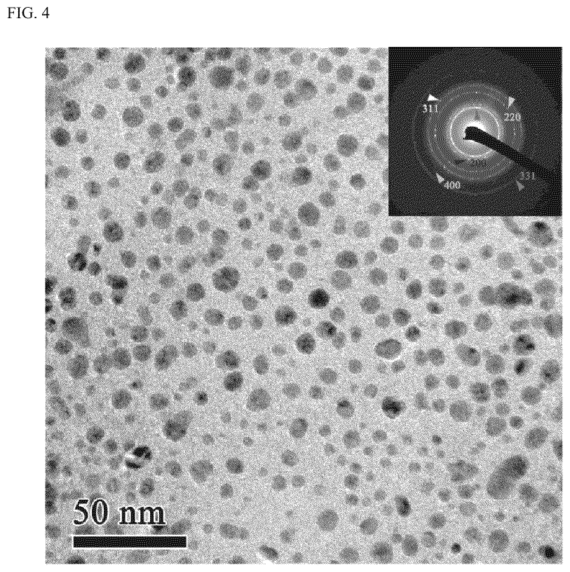

FIG. 3 is a TEM image of diamond particles synthesized in Example 1, and FIG. 4 is a TEM image of diamond particles synthesized in Example 2. As shown in FIG. 3 and FIG. 4, particles with black contrast were generated in Examples 1 and 2. Particles having a particle size of 1 to 60 nm were observed in FIG. 3, and particles having a particle size of 1 to 30 nm were observed in FIG. 4. When the average particle size was measured using ImageJ (ver. 1.51n; open source, public domain image processing software), the average particle size of the particles in Example 1 was 8 nm, and the average particle size of the particles in Example 2 was 12 nm. The particles synthesized in Examples 3 to 10 also had the same appearance.

FIG. 4 shows the selected area electron diffraction (SAED) pattern of the particles of Example 2, which showed clear Bragg reflections. When indexed with Miller indices, the reflections of {111}, {220}, {311}, {400}, and {331} due to the structure of cubic diamond were confirmed, as well as the reflection of {200}. From this, it was found that the obtained particles were diamond particles and had a cubic crystal structure. It was inferred that the reflection of {200} was an extinction reflection due to the cubic diamond structure of the Fd3̅m space group, which appeared due to the multiple scattering effect. It was also confirmed that the particles of Examples 1, 3 to 10 were diamond particles having a cubic crystal structure.

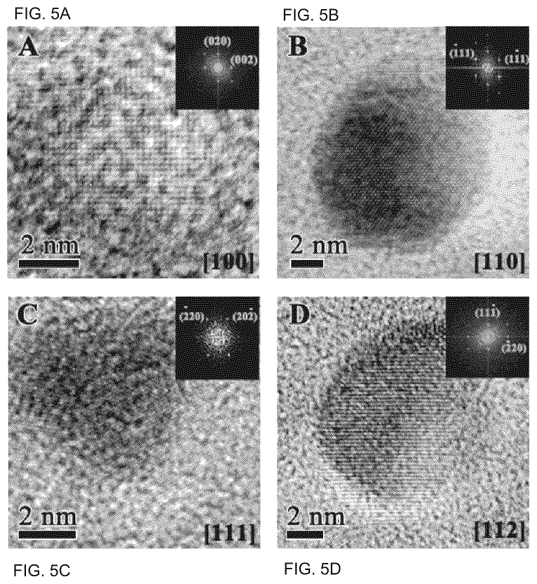

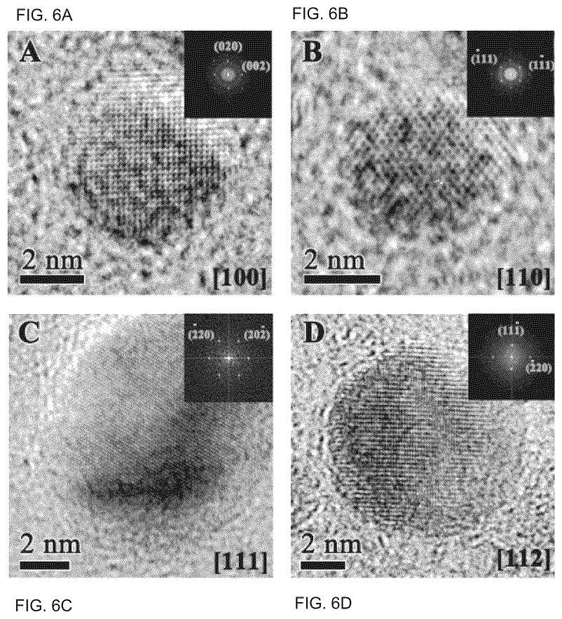

FIGS. 5A to D are HR-TEM images of the diamond particles synthesized in Example 1 observed from various crystal orientations, and FIGS. 6A to D are HR-TEM images of the diamond particles synthesized in Example 2 observed from various crystal orientations. FIGS. 5A to D and 6A to D are HR-TEM images and FFT diffraction patterns of diamond particles along [100], [110], [111], and [112], respectively. From FIGS. 5 and 6, it was confirmed that the diamond particles synthesized in Examples 1 and 2 were single crystals. Further, the diamond particles of Examples 3 to 10 were also single crystals.

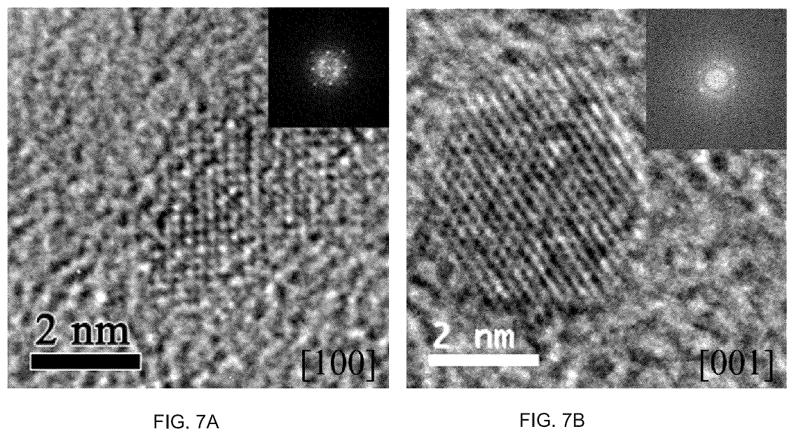

FIGS. 7A and 7B are HR-TEM images of other diamond particles synthesized in Example 2, which are HR-TEM images and FFT diffraction patterns of diamond particles along and [001], respectively. In FIGS. 7A and 7B, hexagonal diamond particles are observed, and thus, it was confirmed that they are single crystal particles with a hexagonal crystal structure. In addition, in Examples 1, 3 to 10, it was confirmed that some diamond particles also have a hexagonal crystal structure.

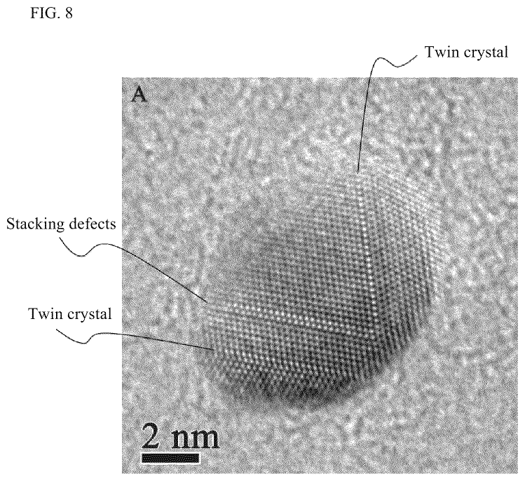

FIG. 8 is an HR-TEM image of other diamond particles synthesized in Example 2. Diamond particles having twin crystal and stacking defects were observed in FIG. 8. Furthermore, particles having crystallographic defects were observed among the diamond particles of Examples 1 and 3 to 10.

It was confirmed from the above results that according to the present invention, diamond particles can be synthesized in a solution using a simpler method.

1. A method for producing diamond particles, comprising
a step of mixing an inorganic salt into a solvent containing 10% by volume or more of an organic solvent containing carbon atoms, to prepare a mixed solution, and
an aging step of holding the mixed solution for a certain period of time under an arbitrary temperature condition,
wherein the inorganic salt is at least one selected from the group consisting of metal halides, metal oxyhalides, metal nitrates, metal phosphates, and metal sulfates.

2. The method for producing diamond particles according to claim 1, wherein the organic solvent is at least one selected from the group consisting of alcohol solvents, ketone solvents, ester solvents, amide solvents, hydrocarbon solvents, aromatic solvents, cellosolve solvents, and halogen solvents.

3. The method for producing diamond particles according to claim 2, wherein the organic solvent contains an alkyl group having an sp3 hybrid orbital.

4. (canceled)

5. The method for producing diamond particles according to claim 1, wherein the inorganic salt contains a metal ion of a Group 1 element, a Group 2 element, a Group 13 element, or a transition metal element.

6. The method for producing diamond particles according to claim 1, wherein the mixed solution has a concentration of the inorganic salt of 0.001 to 1000 g/L.

7. The method for producing diamond particles according to claim 1, wherein the aging step includes holding the mixed solution at a temperature condition of 0 to 400° C. for 0.1 to 1000 hours.

8. The method for producing diamond particles according to claim 1, wherein the aging step includes holding the mixed solution under atmospheric pressure or under the saturated vapor pressure of the solvent.

9. The method for producing diamond particles according to claim 1, which produces diamond particles having a cubic and/or hexagonal crystal structure and having a particle size of 1 to 100 nm.
